(19) United States
(12) Patent Application Publication
(10) Pub. No.: US 2009/0268513 A1
(43) Pub. Date: Oct. 29, 2009

(54) MEMORY DEVICE WITH DIFFERENT TYPES OF PHASE CHANGE MEMORY

(76) Inventors: Luca De Ambroggi, Munich (DE); Jan Boris Philipp, Munich (DE); Peter Schroegmeier, Munich (DE); Gernot Steinlesberger, Otterfing (DE); Christian Pho Duc, Hohenkirchen-Siegertsbrunn (DE); Franz Kreupl, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/111,774

(22) Filed: Apr. 29, 2008

(51) Int. Cl. G11C 11/00; G11C 7/00; H01L 21/00

(52) U.S. Cl. 365/163; 365/148; 365/189.2; 438/102; 257/E21.001

(57) ABSTRACT

A memory includes a first memory device including an array of phase changing memory cells. The first memory device is of a first memory type. The integrated circuit includes a second memory device including an array of phase changing memory cells. The second memory device is of a second memory type that is different than the first memory type. The first and second memory devices are packaged together into a single memory device.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory, such as a phase change random access memory (PCRAM). Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store multiple bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state—“set”—and from the crystalline state to the amorphous state—“reset”—in response to temperature changes. The temperature changes of the phase change material may be achieved by driving current through the phase change material itself or by driving current through a resistive heater adjacent to the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The temperature in the phase change material in each memory cell generally corresponds to the applied level of current and/or voltage to achieve the heating.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

### SUMMARY

One embodiment provides a memory that includes a first memory device including an array of phase changing memory cells. The first memory device is of a first memory type. The integrated circuit includes a second memory device including an array of phase changing memory cells. The second memory device is of a second memory type that is different than the first memory type. The first and second memory devices are packaged together into a single memory device.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating a system with a memory device according to one embodiment.

FIG. 2 is a diagram illustrating a memory device according to one embodiment.

FIG. 3 is a block diagram illustrating a memory device according to another embodiment.

FIG. 4 is a diagram illustrating a package configuration for the memory device shown in FIG. 3 according to one embodiment.

FIG. 5 is a diagram illustrating a package configuration for the memory device shown in FIG. 3 according to another embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

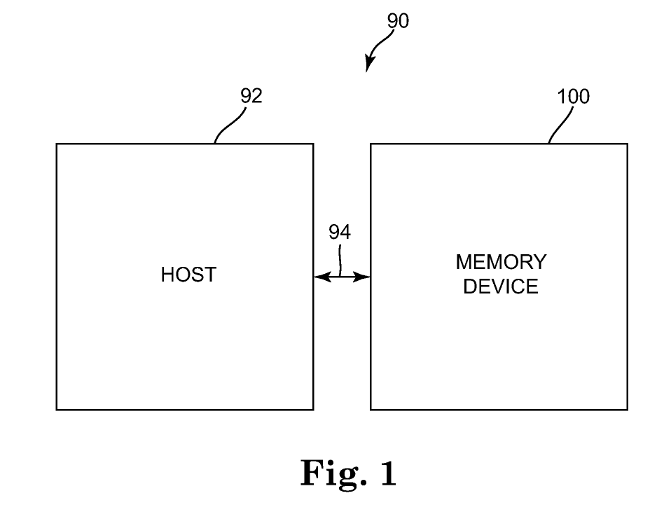

FIG. 1 is a block diagram illustrating a system 90 according to one embodiment. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player, digital camera), or any other suitable device that uses memory. Memory device 100 provides memory for host 92. In one embodiment, memory device 100 includes a phase change memory device or other suitable resistive or resistivity changing material memory device.

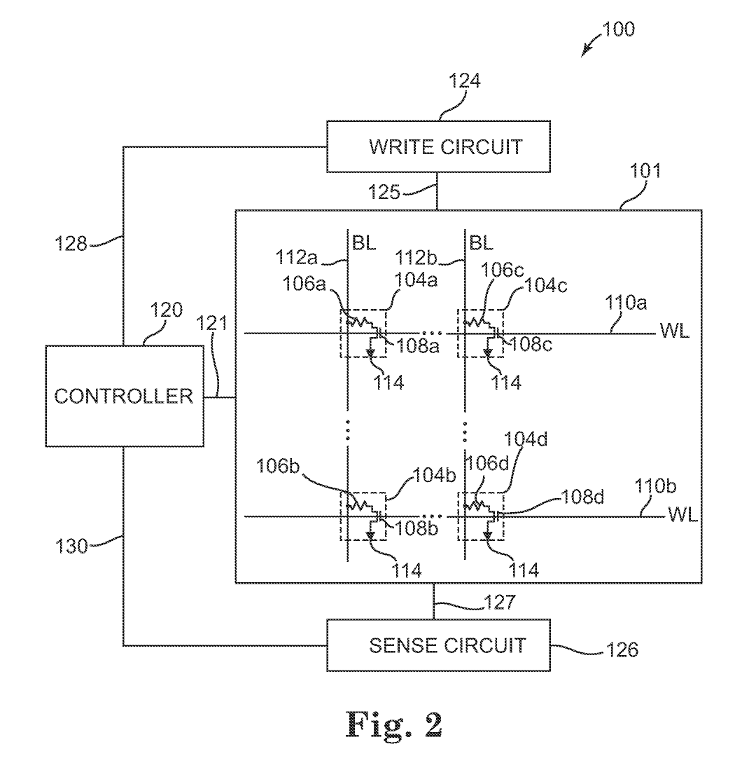

FIG. 2 is a diagram illustrating one embodiment of a memory device 100. In one embodiment, memory device 100 is an integrated circuit or part of an integrated circuit. Memory device 100 includes a write circuit 124, a controller 120, a memory array 101, and a sense circuit 126. Memory array 101 includes a plurality of phase change memory cells 104a-104d (collectively referred to as phase change memory cells 104), a plurality of bit lines (BLs) 112a-112b (collectively referred to as bit lines 112), and a plurality of word lines (WLs) 110a-110b (collectively referred to as word lines 110).

As used herein, the term “electrically coupled” is not meant to mean that the elements must be directly coupled together and intervening elements may be provided between the “electrically coupled” elements.

Memory array 101 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130. Each phase change memory cell 104 is electrically coupled to a word line 110, a bit line 112, and a common or ground 114. Phase change memory cell 104a is electrically coupled to bit line 112a, word line 110a, and common or ground 114, and phase change memory cell 104b is electrically coupled to bit line 112a, word line 110b, and common or ground 114. Phase change memory cell 104c is electrically coupled to bit line 112b, word line 110a, and common or ground 114, and phase change memory cell 104d is electrically coupled to bit line 112b, word line 110b, and common or ground 114.

Each phase change memory cell 104 includes a phase change element 106 and a transistor 108. While transistor 108 is a field-effect transistor (FET) in the illustrated embodiment, in other embodiments, transistor 108 can be another suitable device such as a bipolar transistor or a 3D transistor structure. In other embodiments, a diode or diode-like structure is used in place of transistor 108. In this case, a diode and phase change element 106 are coupled in series between each cross point of word lines 110 and bit lines 112.

Phase change memory cell 104a includes phase change element 106a and transistor 108a. One side of phase change element 106a is electrically coupled to bit line 112a, and the other side of phase change element 106a is electrically coupled to one side of the source-drain path of transistor 108a. The other side of the source-drain path of transistor 108a is electrically coupled to common or ground 114. The gate of transistor 108a is electrically coupled to word line 110a.

Phase change memory cell 104b includes phase change element 106b and transistor 108b. One side of phase change element 106b is electrically coupled to bit line 112a, and the other side of phase change element 106b is electrically coupled to one side of the source-drain path of transistor 108b. The other side of the source-drain path of transistor 108b is electrically coupled to common or ground 114. The gate of transistor 108b is electrically coupled to word line 110b.

Phase change memory cell 104c includes phase change element 106c and transistor 108c. One side of phase change element 106c is electrically coupled to bit line 112b and the other side of phase change element 106c is electrically coupled to one side of the source-drain path of transistor 108c. The other side of the source-drain path of transistor 108c is electrically coupled to common or ground 114. The gate of transistor 108c is electrically coupled to word line 110a.

Phase change memory cell 104d includes phase change element 106d and transistor 108d. One side of phase change element 106d is electrically coupled to bit line 112b and the other side of phase change element 106d is electrically coupled to one side of the source-drain path of transistor 108d. The other side of the source-drain path of transistor 108d is electrically coupled to common or ground 114. The gate of transistor 108d is electrically coupled to word line 110b.

In another embodiment, each phase change element 106 is electrically coupled to a common or ground 114 and each transistor 108 is electrically coupled to a bit line 112. For example, for phase change memory cell 104a, one side of phase change element 106a is electrically coupled to common or ground 114. The other side of phase change element 106a is electrically coupled to one side of the source-drain path of transistor 108a. The other side of the source-drain path of transistor 108a is electrically coupled to bit line 112a.

In one embodiment, each phase change element 106 includes a phase change material that may be made up of a variety of materials. Generally, chalcogenide alloys that contain one or more elements from group VI of the periodic table are useful as such materials. In one embodiment, the phase change material of phase change element 106 is made up of a chalcogenide compound material, such as GeSbTe (“GST”), SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element 106 may be changed from an amorphous state to a crystalline state or from a crystalline state to an amorphous state under the influence of temperature change. The amount of crystalline material coexisting with amorphous material in the phase change material of one of the phase change elements 106a-106d thereby defines two or more states for storing data within memory device 100. In the amorphous state, a phase change material exhibits significantly higher resistivity than in the crystalline state. Therefore, the two or more states of phase change elements 106a-106d differ in their electrical resistivity. In one embodiment, the two or more states are two states and a binary system is used, wherein the two states are assigned bit values of “0” and “1”. A memory cell with two possible states is referred to herein as a single-level cell (SLC). In another embodiment, the two or more states are three states and a ternary system is used, wherein the three states are assigned bit values of “0”, “1”, and “2”. In another embodiment, the two or more states are four states that can be assigned multi-bit values, such as “00”, “01”, “10”, and “11”. In other embodiments, the two or more states can be any suitable number of states in the phase change material of a phase change element. A memory cell with more than two possible states is referred to herein as a multiple-level cell (MLC).

Controller 120 includes a microprocessor, microcontroller, or other suitable logic circuitry for controlling the operation of memory device 100. Controller 120 controls read and write operations of memory device 100 including the application of control and data signals to memory array 101 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In another embodiment, sense circuit 126 provides voltage across one of the memory cells 104 and reads the current that flows through that one of the memory cells 104. In another embodiment, write circuit 124 provides voltage across one of the memory cells 104 and sense circuit 126 reads the current that flows through that one of the memory cells 104. In another embodiment, write circuit 124 provides current that flows through one of the memory cells 104 and sense circuit 126 reads the voltage across that one of the memory cells 104.

During a set operation of phase change memory cell 104a, word line 110a is selected to activate transistor 108a. With word line 110a selected, one or more set current or voltage pulses are selectively enabled by write circuit 124 and sent through bit line 112a to phase change element 106a. The set current or voltage pulses heat phase change element 106a above its crystallization temperature (but usually below its melting temperature). In this way, phase change element 106a reaches the crystalline state or a partially crystalline and partially amorphous state during this set operation.

During a reset operation of phase change memory cell 104a, word line 110a is selected to activate transistor 108a. With word line 110a selected, a reset current or voltage pulse is selectively enabled by write circuit 124 and sent through bit line 112a to phase change element 106a. The reset current or voltage quickly heats phase change element 106a above its melting temperature. After the current or voltage pulse is turned off, phase change element 106a quickly quench cools into the amorphous state or a partially amorphous and partially crystalline state. Phase change memory cells 104b-104d and other phase change memory cells 104 in memory array 101 are set and reset similarly to phase change memory cell 104a using similar current or voltage pulses.

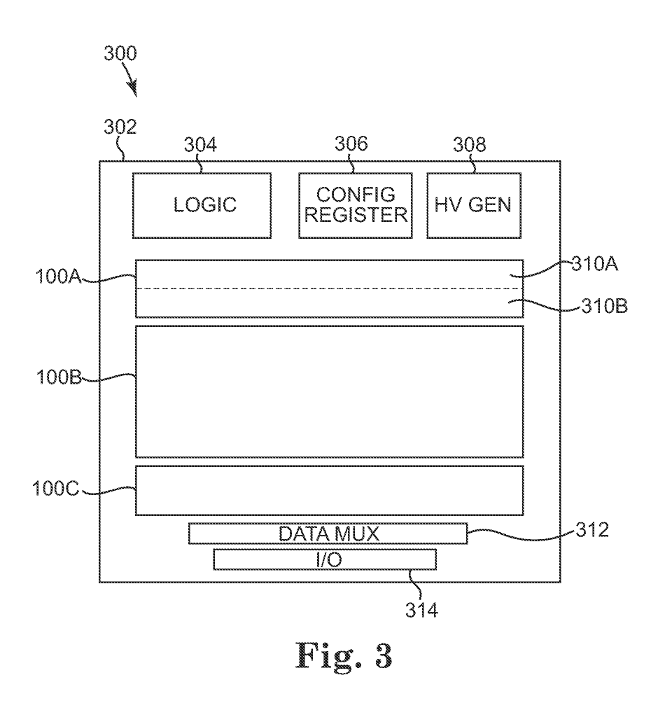

FIG. 3 is a block diagram illustrating a memory device 300 according to another embodiment. Memory device 300 includes logic 304, configuration registers 306, high voltage generation (HV Gen) unit 308, memory devices 100A-100C, data multiplexer (Mux) 312, and input/output (I/O) interface 314, which are all integrated together in a package represented by reference number 302. In one embodiment, memory devices 100A-100C are each a phase change memory device, such as memory device 100 shown in FIG. 2 and described above. In one embodiment, memory devices 100A-100C are all implemented together in a single semiconductor die (e.g., a two-dimensional approach) and packaged in a single semiconductor chip. In another embodiment, memory devices 100A-100C are each implemented in a separate semiconductor die, and the multiple semiconductor dies are then packaged together in package 302 (e.g., in a multi-chip package or MCP configuration, which is also referred to herein as a three-dimensional approach). Although three memory devices 100A-100C are shown in the illustrated embodiment, in other embodiments, more or less than three memory devices are integrated together in package 302.

In one embodiment, memory devices 100A-100C are each a different type or “flavor” of phase change memory device. In another embodiment, at least two different types or flavors of phase change memory devices are provided in device 300. The memory types or flavors according to one embodiment include volatile memory types such as DRAM and SRAM, and non-volatile memory types such as NAND and NOR. In other embodiments, other types of memory devices may be used. The number and types of memory devices that are used in a given package 302 will vary depending upon the application in which the memory device 300 will be used.

In one embodiment, the different types of the phase change memory devices are achieved by using different phase change materials, and/or different doping materials or different doping levels, for each of the three memory devices 100A-100C, which results in different properties, performance, and features for the memory devices. In one embodiment, the same process line is used to process memory devices 100A-100C, and the different types of memory devices are achieved by changing the phase change cell material in order to match the desired performance and features. In addition to using different phase change materials, process variations and the implementation of different devices or devices with different properties (e.g., using different cell select transistors) may also be performed in one embodiment to achieve phase change memory devices of different types and functionality.

In one embodiment, one or more of memory devices 100A-100C include two or more sub-types of memory. In the illustrated embodiment, memory device 100A is divided into a first portion with a first sub-type 310A and a second portion with a second sub-type 310B. In one embodiment, sub-type 310A represents a single-level cell (SLC) configuration, and sub-type 310B represents a multi-level cell (MLC) configuration. In another embodiment, the sub-types within a given memory device represent other functionality or feature differences, such as speed, data reliability (e.g., endurance/retention), current consumption, voltage levels (e.g., a high voltage sub-type and a low-voltage sub-type).

In one embodiment, logic 304 controls the operation of memory device 300, including, for example, receiving read and write commands transmitted by host 92 (FIG. 1), and accessing the appropriate one of the memory devices 100A-100C to execute each command. High voltage generation unit 308 generates high voltage signals for any of the memory devices 100A-100C that are configured as high voltage devices. In the embodiment illustrated in FIG. 3, device 300 includes a single input/output interface 314 that is shared by the three memory devices 100A-100C. In one embodiment, data is transferred between host 92 and memory devices 100A-100C via the shared or common input/output interface 314, which is configured to be coupled to communication link 94 (FIG. 1). Data multiplexer 312 selectively controls which of the memory devices 100A-100C will be using the input/output interface 314 at any given time. In one embodiment, input/output interface 314 is a double data rate (DDR) interface and memory devices 100A-100C communicate with host 92 using a DDR interface protocol. The use of a shared or common input/output interface for multiple memory devices 100A-100C according to one embodiment reduces system complexity, pins, and costs, and allows multiple different memory flavors to interact with the host 92 through a single shared bus.

As mentioned above, memory devices 100A-100C according to one embodiment are of different types or flavors. In one embodiment, configuration registers 306 are used to configure one or more of the memory devices 100A-100C to also have different memory sub-types, or to cause the memory devices 100A-100C to have other different performance differences or feature differences. Parameter selection for each of the memory devices 100A-100C is accomplished in one embodiment by programming the configuration registers 306 in order to set up the memory devices 100A-100C according to the specifications of the application. Some examples of memory parameters or features that are software configurable using configuration registers 306 according to one embodiment include parameters for setting or resetting specific circuitry, and selecting an algorithm for each memory device 100A-100C to facilitate optimization of the memory performances according to the specifications of the application or the host 92.

In one embodiment, configuration registers 306 are configured to be accessible and programmable only during testing. In another embodiment, configuration registers 306 are also accessible and programmable via a user mode in which, for example, a test engineer or user can access the registers 306 and set predetermined values to configure each of the memory devices 100A-100C to have various predetermined features. In one embodiment, configuration registers 306 are programmable to cause one or more of the memory devices 100A-100C to have either an SLC configuration or an MLC configuration, and to cause one or more of the memory devices 100A-100C to have one portion of the memory device operating in an SLC configuration and another portion of the same memory device operating in an MLC configuration. In one embodiment, configuration registers 306 are programmable to define speed and data reliability characteristics of each of the memory devices 100A-100C.

As mentioned above, configuration registers 306 according to one embodiment may be used to select an algorithm for each memory device 100A-100C to facilitate optimization of the memory performances. Algorithms may be chosen for each memory device 100A-100C to provide the best compromise among performance, power, and/or reliability of the memory devices. For example, in applications where reliability of programmed data is of higher importance than power consumption and/or speed, an algorithm that provides more accurate or wider set pulses during the programming of memory cells may be selected in order to have a tight and stable cell distribution and better reliability, at the possible expense of higher power and slower speed. Similarly, in applications where high speed and/or low power consumption are more important than data reliability (e.g., the application may rely on error correction codes (ECC) or other error correction methods to increase data reliability) an algorithm that provides less accurate or narrower pulses during the programming of memory cells may be selected.

In one embodiment, the amplitude and width (i.e., duration) of set and reset pulses for setting and resetting the memory cells 104 of one or more of the memory devices 100A-100C are programmable via the configuration registers 306. The greater the error tolerance for the data stored in memory devices 100A-100C, the shorter the pulse width may be, thus increasing the overall speed of the memory device. In one embodiment, memory devices 100A-100C are configured using different phase change materials and via configuration registers 306 to provide: A first phase change memory device 100A that is configured as a NOR-type memory with high reliability and lower speed and having a first portion 310A with MLC functionality and a second portion 310B with SLC functionality; a second phase change memory device 100B that is configured as a DRAM-type memory; and a third phase change memory device 100C that is configured as a NOR-type memory with lower reliability and higher speed than memory device 100A. In other embodiments, phase change memory devices 100A-100C may be configured to have other types and characteristics.

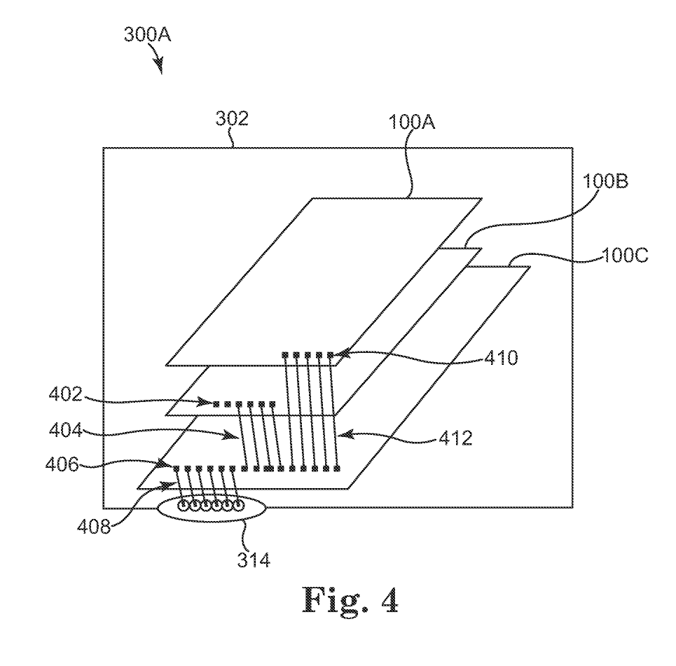

FIG. 4 is a diagram illustrating a package configuration for the memory device 300 shown in FIG. 3 according to one embodiment. The embodiment of the memory device 300 shown in FIG. 4 is identified by reference number 300A. In the illustrated embodiment, memory devices 100A-100C are implemented in separate semiconductor dies or chips, which are packaged together in a stacked arrangement in package 302 in a multi-chip package configuration.

Memory device 100A includes a plurality of input/output pads 410. Memory device 100B includes a plurality of input/output pads 402. Memory device 100C includes a plurality of input/output pads 406. Input/output pads 410 of memory device 100A are coupled to input/output pads 406 of memory device 100C via communication links 412. Input/output pads 402 of memory device 100B are coupled to input/output pads 406 of memory device 100C via communication links 404. Input/output pads 406 of memory device 100C are coupled to input/output interface 314 via communication links 408. Input/output interface 314 is configured to be coupled to host 92 via communication link 94.

In one embodiment, interface 314 is shared by the three memory devices 100A-100C, and data is transferred between host 92 and memory devices 100A-100C through interface 314. In the illustrated embodiment, memory device 100C is connected directly to interface 314 via communication links 408, and includes logic to communicate directly with the host 92. In contrast, memory devices 100A and 100B are not directly connected to interface 314 in the illustrated embodiment, and do not communicate directly with the host 92. Rather memory devices 100A and 100B communicate with host 92 through memory device 100C, which has logic to control the transfer of data between host 92 and memory devices 100A and 100B. In another embodiment, memory devices 100A-100C are each directly connected to interface 314, or memory devices 100A-100C each use their own separate input/output interface.

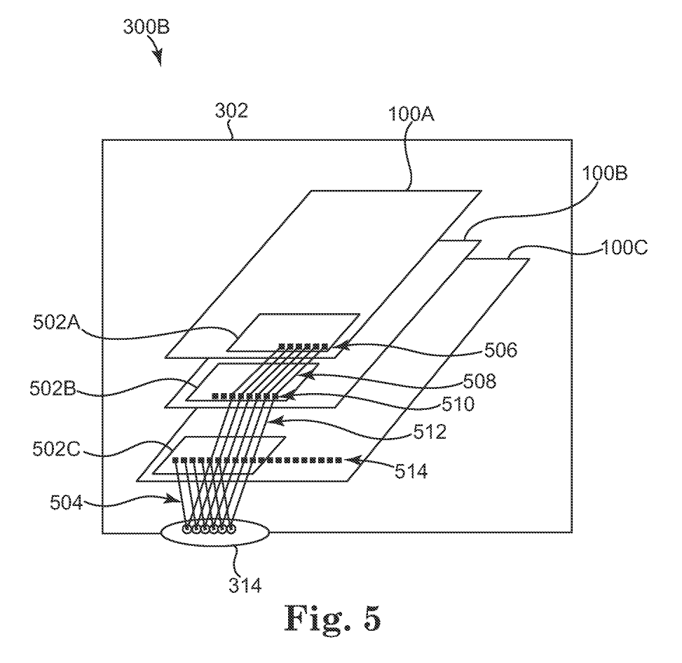

FIG. 5 is a diagram illustrating a package configuration for the memory device 300 shown in FIG. 3 according to another embodiment. The embodiment of the memory device 300 shown in FIG. 5 is identified by reference number 300B. In the illustrated embodiment, memory devices 100A-100C are implemented in separate semiconductor dies or chips, which are packaged together in a stacked arrangement in package 302 in a multi-chip package configuration.

Memory device 100A includes a plurality of input/output pads 506. Memory device 100B includes a plurality of input/output pads 510. Memory device 100C includes a plurality of input/output pads 514. Input/output pads 506 of memory device 100A are coupled to input/output pads 510 of memory device 100B via communication links 508. The input/output pads 510 of memory device 100B that are coupled to memory device 100A via communication links 508 are also coupled to input/output interface 314 via communication links 512. Input/output pads 514 of memory device 100C are coupled to input/output interface 314 via communication links 504. Input/output interface 314 is configured to be coupled to host 92 via communication link 94.

In one embodiment, interface 314 is shared by the three memory devices 100A-100C, and data is transferred between host 92 and memory devices 100A-100C through interface 314. In the illustrated embodiment, memory devices 100A-100C are all connected directly to interface 314. Memory devices 100A-100C include logic 502A-502C, respectively, for communicating directly with the host 92.

One embodiment provides a method of manufacturing a memory device 300. The method according to one embodiment includes forming a first memory array 101 including a plurality of phase changing memory cells 104 using a first phase change material for each cell in the first array, and forming a second memory array 101 including a plurality of phase changing memory cells 104 using a second phase change material for each cell in the second array that is different than the first phase change material. The first and second memory arrays are packaged together into a single memory device 300 in one embodiment. The method according to one embodiment further includes forming a shared input/output interface 314, wherein both of the first memory array and the second memory array are configured to communicate with an external device (e.g., host 92) via the shared input/output interface 314.

One embodiment provides a phase change memory integrated circuit with multiple types or flavors of memory implemented in a single semiconductor die or package. In one embodiment, circuitry is shared by multiple memory devices in the package, resulting in a reduced area consumption. The flexible approach for configuring the memory devices to be of different types and have different features and functionality according to one embodiment provides a reduction in overall memory system overhead. One embodiment of the multiple-type phase change memory device includes a common memory input/output interface that is shared by multiple different types of memory devices, which results in a system with reduced complexity and costs.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory comprising:
a first memory device including an array of phase changing memory cells, the first memory device being of a first memory type;
a second memory device including an array of phase changing memory cells, the second memory device being of a second memory type that is different than the first memory type; and
wherein the first and second memory devices are packaged together into a single memory device.

2. The memory of claim 1, and further comprising:
a third memory device including an array of phase changing memory cells, the third memory device being of a third memory type that is different than the first and second memory types, and wherein the first, second, and third memory devices are packaged together into the memory device.

3. The memory of claim 1, wherein the first and second memory devices are integrated together in a single semiconductor die and wherein the single memory device is a single semiconductor chip.

4. The memory of claim 1, wherein the first and second memory devices are implemented on separate semiconductor dies and the single device is a multi-chip package.

5. The memory of claim 1, wherein the first memory type is a volatile memory type and the second memory type is a non-volatile memory type.

6. The memory of claim 1, wherein the first memory type and the second memory type are each one of NOR, NAND, DRAM, and SRAM.

7. The memory of claim 1, and further comprising:
a shared input/output interface; and
wherein both of the first memory device and the second memory device are configured to communicate with an external device via the shared input/output interface.

8. The memory of claim 7, wherein the shared input/output interface is a DDR input/output interface.

9. The memory of claim 1, wherein at least one of the first memory device and the second memory device include a first memory sub-type and a second memory sub-type.

10. The memory of claim 9, wherein the first memory sub-type is a single-level cell (SLC) configuration, and the second memory sub-type is a multi-level cell (MLC) configuration.

11. The memory of claim 1, and further comprising:
at least one configuration register that is programmable to configure the first and second memory devices.

12. The memory of claim 11, wherein the configuration register is programmable to cause at least one of the first memory device and the second memory device to have a single-level cell (SLC) configuration or a multi-level cell (MLC) configuration.

13. The memory of claim 11, wherein the configuration register is programmable to define speed and data reliability characteristics of at least one of the first memory device and the second memory device.

14. The memory of claim 11, wherein the configuration register is programmable to define a width of pulses that are applied to at least one of the first memory device and the second memory device.

15. The memory of claim 11, wherein the configuration register is programmable to define an amplitude of pulses that are applied to at least one of the first memory device and the second memory device.

16. A system comprising:
a host; and
a memory communicatively coupled to the host, the memory including a plurality of phase change memory devices, each phase change memory device including a plurality of phase changing memory cells, the plurality of phase change memory devices including at least two different types of phase change memory devices, and wherein the plurality of phase change memory devices are packaged together into a single memory device.

17. The system of claim 16, wherein the two different types are each one of NOR, NAND, DRAM, and SRAM.

18. The system of claim 16, wherein at least one of the phase change memory devices include both a single-level cell (SLC) portion, and a multi-level cell (MLC) portion.

19. A method of manufacturing a memory device, comprising:
forming a first memory array including a plurality of phase changing memory cells using a first phase change material for each cell in the first array;
forming a second memory array including a plurality of phase changing memory cells using a second phase change material for each cell in the second array that is different than the first phase change material; and
packaging the first and second memory arrays into a single memory device.

20. The method of claim 19, and further comprising:
forming a shared input/output interface, wherein both of the first memory array and the second memory array are configured to communicate with an external device via the shared input/output interface.
